(19) United States
(12) Patent Application Publication
(10) Pub. No.: US 2017/0245358 A1
(43) Pub. Date: Aug. 24, 2017

(54) Adhesion Promoting Material-Coated Electrically Conductive Carrier With Thermally Conductive Layer

(71) Applicant: AT & S Austria Technologie & Systemtechnik Aktiengesellschaft, Leoben (AT)

(72) Inventors: Elisabeth Kreutzwiesner, Graz (AT); Gernot Schulz, Graz (AT)

(21) Appl. No.: 15/501,839

(22) PCT Filed: Aug. 4, 2015
(86) PCT No.: PCT/EP2015/067983

§ 371 Date: Feb. 4, 2017

(30) Foreign Application Priority Data
Aug. 5, 2014 (DE) 10 2014 111 145.1

(51) Int. Cl. H05K 1/02; H05K 1/03; H05K 1/11; H05K 3/22; C23C 16/27; H01L 23/373; H01L 21/48; C23C 14/06; C23C 14/34; H05K 1/09; H01L 23/498

(52) U.S. Cl. CPC H05K 1/0204; H05K 1/09; H05K 1/0313; H05K 1/115; H05K 3/22; H01L 23/49822; H01L 23/49827; H01L 23/49838; H01L 23/49866; H01L 23/373; H01L 21/4846; C23C 14/0611; C23C 14/34; C23C 16/276; H05K 2201/0179; H05K 2201/0195; H05K 2201/0358

(57) ABSTRACT

A composite structure for use as a constituent of a mounting device, wherein the composite structure comprises an electrically conductive carrier, an intermediate layer comprising adhesion promoting material and being arranged on the electrically conductive carrier, and a thermally conductive and electrically insulating layer on the intermediate layer.

### CROSS-REFERENCE TO RELATED APPLICATIONS

This application claims the benefit of the filing date of German Patent Application No. 10 2014 111 145.1 filed 5 Aug. 2014, the disclosure of which is hereby incorporated herein by reference.

### TECHNICAL FIELD

Embodiments of the invention relate to a composite structure, a mounting device, a method of manufacturing a composite structure, and a method of manufacturing a mounting device.

Technological Background

In the context of growing product functionalities of mounting devices equipped with one or more electronic components and increasing miniaturization of such electronic components as well as a rising number of electronic components to be mounted on mounting devices such as printed circuit boards, increasingly more powerful array-like components or packages having several electronic components are being employed, which have a plurality of contacts or connections, with ever smaller spacing between these contacts. Removal of heat generated by such electronic components and the mounting device itself during operation becomes an increasing issue. At the same time, mounting devices shall be mechanically robust so as to be operable even under harsh conditions.

U.S. Pat. No. 6,824,880 B1 discloses a multilayer foil which may be embedded in a printed circuit board. The multilayer foil comprises a copper foil and a resistive metal layer which is deposited on the copper foil. On a surface of the resistive metal layer, a layer of an adhesion-promoting material is applied. The multilayer foil further comprises a prepreg layer adhered to the resistive metal layer by the adhesion-promoting material.

US 2012/0 168 217 A1 discloses an embedded capacitor substrate module which comprises a metal substrate, a solid electrolytic capacitor material, and a thermally conductive and electrically insulating layer, which is made of e.g. aluminum oxide. An upper surface of the thermally conductive and electrically insulating layer is covered with the solid electrolytic capacitor material and a lower surface of the thermally conductive and electrically insulating layer is covered with the metal substrate.

US 2009/0 237 886 A1 discloses a carbon nanotube sheet comprising a plurality of linear structures with carbon atoms (carbon nanotubes) with a high electric and thermal conductivity. The carbon nanotube sheet further comprises a filling material arranged between the nanotubes, and a coating film which can be made of e.g. copper, nickel, alloys, etc. The carbon nanotube sheet may be embedded in a printed circuit board, thereby contributing to heat dissipation towards a heat sink.

U.S. Pat. No. 4,457,952 A discloses a method of manufacturing a printed circuit board. The printed circuit board comprises an electrically insulating substrate, an adhesive layer which contains an alkaline earth metal carbonate powder, an electrically conductive circuit, and a resist ink film mask. The conductive circuit is formed on the adhesive layer by means of a catalyst for electroless plating.

### SUMMARY

There may be a need to provide an architecture for mounting devices which allows to provide a proper heat dissipation while ensuring high mechanical stability.

In order to achieve this need, a composite structure, a mounting device, and a method of manufacturing a composite structure according to the independent claims are provided.

According to an exemplary embodiment of the invention, a composite structure for use as a constituent of a mounting device is provided, wherein the composite structure comprises an electrically conductive carrier, an intermediate layer comprising adhesion promoting material and being arranged on the electrically conductive carrier, and a thermally conductive and electrically insulating layer on the intermediate layer.

According to another exemplary embodiment of the invention, a mounting device for mounting electronic components is provided, wherein the mounting device comprises a base structure comprising an electrically conductive structure and an electrically insulating structure, and at least one composite structure having the above mentioned features which is attached at its thermally conductive and electrically insulating layer to at least one main surface of the base structure.

According to yet another exemplary embodiment of the invention, a method of manufacturing a composite structure for use as a constituent of a mounting device is provided, wherein the method comprises providing an intermediate layer, which comprises adhesion promoting material, on an electrically conductive carrier, and forming a thermally conductive and electrically insulating layer on the intermediate layer.

According to still another exemplary embodiment of the invention, a method of manufacturing a mounting device for mounting electronic components is provided, wherein the method comprises manufacturing a composite structure according to the method having the above mentioned features, providing a base structure comprising an electrically conductive structure and an electrically insulating structure, and attaching the thermally conductive and electrically insulating layer of the composite structure to at least one of main surfaces of the base structure.

In the context of the present application, a “layer” may denote a planar film or sheet or foil (see FIG. 1) or a three-dimensionally bent film or sheet or foil or even a closed, for example tubular, jacket (see FIG. 5). A layer may have a thickness which is significantly smaller than its extension in other directions. For instance, the extension in length and width direction of a planar layer may be at least five times, in particular at least ten times, of the thickness of the planar layer. A layer may be continuous or patterned.

In the context of the present application, a “mounting device” may denote a (particularly plate shaped) body which has an electrically insulating portion and one or more electrically conductive structures on at least one surface of the mounting device. Such a mounting device may serve as a basis for mounting one or more electronic components (such as packaged electronic chips, active and/or passive electronic members, sockets, etc.) thereon and/or therein and serves both as a mechanical support platform and an electrically wiring arrangement.

According to an exemplary embodiment, a composite structure of an electric conductor, an adhesion promoting material comprising intermediate layer and a thermally conductive dielectric layer is provided which can serve as a substitute for conventional electrically conductive structures used for fulfilling electronic functions in a mounting device such as a printed circuit board. The provision of such a stack of layers and/or structures has the advantage that the capability of transmitting electric signals is combined with a high thermal conductivity. At the same time, a strong mechanical robustness renders the composite structure appropriate even for applications under harsh conditions. The electric conductivity is provided by the electrically conductive carrier. The high thermal conductivity resulting in the capability of an efficient removal of heat generated during operation of the mounting device can be accomplished by the thermally conductive and electrically insulating layer, which at the same time, due to its dielectric properties, does not disturb the electric function of the composite structure or the mounting device. Since thermally conductive and electrically insulating materials (such as diamond like carbon) show in many cases a poor adhesion on appropriate electrically conductive materials (such as copper), adhesion promoting material (such as resin) material of the intermediate layer may promote adhesion while at the same time being a material compatible with mounting devices such as printed circuit boards. This improves the mechanical stability of the composite structure and the mounting device.

In the following, further exemplary embodiments of the composite structure, the mounting device and the methods will be explained.

In an embodiment, the adhesion promoting material may comprise resin and/or silane.

In an embodiment, the electrically conductive carrier is an electrically conductive layer such as a foil. It may alternatively be another type of structure, such as a cylinder, a post or a cuboid.

In an embodiment, the electrically conductive carrier comprises or consists of copper. Copper is highly appropriate due to its high electrical and thermal conductivity. However, alternative materials are possible for the electrically conductive carrier, such as an aluminum or nickel or electrically conductive polymers.

In an embodiment, the intermediate layer consists of one of the group consisting of pure resin, prepreg, and resin soaked glass fibres. It is however preferred that the intermediate layer consists of pure resin (in particular resin without glass cloth). This ensures, in view of the sticky properties of resin, a proper adhesion of the thermally conductive and electrically insulating layer on the electrically conductive carrier, intermediated by the interposed resin. Furthermore, preformed composite structures of resin on copper (so-called Resin Coated Copper, RCC, foils) can be used as a basis for manufacturing a composite structure according to an exemplary embodiment of the invention by depositing or printing a thermally conductive and electrically insulating layer thereon.

In an embodiment, the resin comprises or consists of epoxy resin. Epoxy resins, also known as polyepoxides are a class of reactive prepolymers and polymers which contain epoxide groups. Epoxy resins may be reacted (cross-linked) with themselves through catalytic homopolymerisation, or with a wide range of co-reactants including polyfunctional amines, acids (and acid anhydrides), phenols, alcohols, and thiols.

In an embodiment, the thermally conductive and electrically insulating layer comprises or consists of one of the group consisting of diamond-like carbon (DLC), a nitride (in particular a metal nitride such as aluminum nitride, etc.), and an oxide (in particular a metal oxide such as aluminum oxide, zinc oxide, etc.).

In the context of the present application, the term “diamond-like carbon” (DLC) may be denoted as a mixture of different forms of amorphous and/or crystalline carbon materials which may have both graphitic and diamond like characteristics. DLC may contain adjustable (for instance by selecting a certain DLC production method and/or by correspondingly adjusting process parameters of a selected production method) amounts of sp² hybridized carbon atoms and/or sp³ hybridized carbon atoms. By mixing these polytypes in various ways at the nanoscale level of structure, a DLC structure as thermally conductive and electrically insulating layer can be made that at the same time is amorphous, flexible, and yet of sp³ bonded diamond type.

In an embodiment, the thermally conductive and electrically insulating layer is made of a material having a value of the thermal conductivity of at least 2 W/m K, in particular at least 50 W/m K, more particularly at least 400 W/m K. Such values of the thermal conductivity are significantly better than the thermal conductivity of conventionally used electrically insulating materials (for instance FR4: ≈0.3 W/mK) of mounting devices such as printed circuit boards, which therefore significantly improves the heat removal from the mounting device during operation of the mounting device with electronic components (such as packaged semiconductor chips, etc.) mounted thereon.

In an embodiment, a thickness of the thermally conductive and electrically insulating layer is in a range between 150 nm and 50 μm, in particular in a range between 750 nm and 10 μm, more particularly in a range between 1 μm and 3 μm. When the thickness becomes too small, the impact on the desired increase of the thermal conductivity becomes too small. When the thickness becomes however too large, the mechanical stability of the thermally conductive and electrically insulating layer may suffer. Therefore, in particular for DLC, the given ranges have turned out to be a proper trade-off between these two technical requirements.

In an embodiment, the electrically conductive carrier (in particular when embodied as a layer or foil) and the intermediate layer together have a thickness in a range between 4 μm and 100 μm, in particular in a range between 9 μm and 18 μm. Thus, sufficiently thin and nevertheless mechanical stable composite structures may be obtained meeting both requirements of being sufficiently robust under typical application conditions as well as promoting the trend of continued miniaturization.

In an embodiment, the composite structure further comprises a cover layer covering the thermally conductive and electrically insulating layer, in particular comprising adhesion promoting material such as resin. By providing such an additional cover layer (which may also be made of pure resin) it is possible to improve adhesion properties of the composite structure on any desired base structure of a mounting device to be manufactured using the composite structure. Since the adhesion properties on some materials (in particular copper) of appropriate thermally conductive and electrically insulating materials such as DLC may be poor, the mechanical stability of the entire mounting device may be further significantly improved by additionally providing the cover layer as adhesion promoter.

In an embodiment, the composite structure further comprises at least one via extending through at least part of the composite structure and being filled with a thermally conductive material (for instance the same material as the electrically conductive carrier, such as copper) to thereby thermally couple the thermally conductive and electrically insulating layer to the electrically conductive carrier by the at least one via through the intermediate layer. In such an embodiment, heat spreading can be accomplished by thermally connecting heat sources at any positions of the mounting device with the thermally conductive and electrically insulating layer functioning as spreading layer. This significantly increases the lifetime of the mounting device.

In an embodiment, the composite structure is configured as a layer sequence or multilayer substrate. In the context of the present application, a “layer sequence” may denote a stack of layers.

In an embodiment, the electrically conductive structure of the mounting device comprises or consists of copper. Copper is highly appropriate due to its high electrical and thermal conductivity. However, alternative materials are possible for the electrically conductive structure, such as an aluminum or nickel.

In an embodiment, the electrically insulating structure comprises or consists of at least one of the group consisting of prepreg, resin, FR4, and resin soaked glass fibres. In particular, the electrically insulating structure may be or may be based on prepreg material (such as a prepreg sheet or prepreg islands). Such prepreg material may form at least partially an electrically insulating structure of a glass fiber reinforced epoxy-based resin and may be shaped as a for instance patterned plate or sheet. Prepreg may be denoted as a glass fiber mat soaked by resin material and may be used for an interference fit assembly for the manufacture of mounting devices such as printed circuit boards. FR4 may designate a glass-reinforced epoxy material, for instance shaped as laminate sheets, tubes, rods, or plates. FR4 is a composite material composed of woven fiberglass cloth with an epoxy resin binder that is flame resistant. Such an electrically insulating structure may also be formed as a stack of a plurality of electrically insulating layers (for instance made of prepreg, FR4, etc.), optionally having thermally conductive and electrically insulating layers in between.

In an embodiment, an exposed surface of the thermally conductive and electrically insulating layer is, partially or entirely, directly connected to the electrically insulating structure. While preferred materials for the thermally conductive and electrically insulating layer, for instance DLC, show a poor adhesion on electrically conductive materials such as copper, the adhesion of such materials on appropriate materials for the electrically insulating structure (such as prepreg or FR4) are good. Therefore, a direct connection between the thermally conductive and electrically insulating layer on the one hand and the electrically insulating structure on the other hand is possible and maintains the entire mounting device compact without compromising on the mechanical stability.

In an embodiment, the mounting device comprises a further composite structure having the above mentioned features, wherein the base structure is sandwiched between the composite structure and the further composite structure. Thus, a symmetric configuration of the base structure with respect to the at least two composite structures may be obtained. Furthermore, such an embodiment allows to construct even more complex mounting devices fulfilling even sophisticated electronic applications.

In an embodiment, the mounting device is configured as one of the group consisting of a circuit board (for instance a printed circuit board), an interposer, and a substrate.

In the context of the present application, a “circuit board” may denote a particularly plate shaped body which has an electrically insulating core and electrically conductive structures on at least one surface of the circuit board. Such a circuit board may serve as a basis for mounting electronic members thereon and/or therein and serves both as a mechanical support platform and an electrically wiring arrangement.

In the context of the present application, a “printed circuit board” (PCB) may denote a board of an electrically insulating core (in particular made of a compound of glass fibers and resin) covered with electrically conductive material and conventionally serving for mounting thereon one or more electronic members (such as packaged electronic chips, sockets, etc.) to be electrically coupled by the electrically conductive material. More specifically, a PCB may mechanically support and electrically connect electronic components using conductive tracks, pads and other features etched from metal structures such as copper sheets laminated onto an electrically non-conductive substrate. PCBs can be single sided (i.e. may have only one of its main surfaces covered by a, in particular patterned, metal layer), double sided (i.e. may have both of its two opposing main surfaces covered by a, in particular patterned, metal layer) or of multi-layer type (i.e. having also one or more, in particular patterned, metal layers in its interior). Conductors on different layers may be connected to one another with holes filled with electrically conductive material, which may be denoted as vias. The corresponding holes (which may be through holes or blind holes) may be formed for instance mechanically by boring, or by laser drilling. PCBs may also contain one or more electronic components, such as capacitors, resistors or active devices, embedded in the electrically insulating core.

In the context of the present application, an “interposer” may denote an electrical interface device routing between one connection to another. A purpose of an interposer may be to spread a connection to a wider pitch or to reroute a connection to a different connection. One example of an interposer is an electrical interface between an electronic chip (such as an integrated circuit die) to a ball grid array (BGA).

In the context of the present application, a “substrate” may denote a physical body, for instance comprising a ceramic material, onto which electronic components are to be mounted. Such substrates may comprise one or more amorphous materials, such as for instance glass.

In an embodiment, the electrically conductive carrier and the intermediate layer are configured as a Resin Coated Copper (RCC) foil. Such RCC foils are available commercially and need only be covered with thermally conductive and electrically insulating material to thereby obtain a composite structure according to an exemplary embodiment. This can be done by carrying out an appropriate deposition or printing procedure.

In an embodiment, the thermally conductive and electrically insulating layer is formed on the intermediate layer by deposition. In particular, the thermally conductive and electrically insulating layer is formed on the intermediate layer by one of the group consisting of physical vapor deposition (PVD), cathodic arc deposition (ARC), chemical vapour deposition (CVD), and plasma enhanced chemical vapour deposition (PECVD). In particular, the formation may be performed by ARC, which is a physical vapor deposition technique in which an electric arc is used to vaporize material from a cathode target. Thus, the thermally conductive and electrically insulating layer formed on the intermediate layer may be formed by deposition on the underlying intermediate layer. It is however also possible to form the thermally conductive and electrically insulating layer on the intermediate layer by printing.

In an embodiment, the attaching is performed by pressing the composite structure and the base structure together. In other words, mechanical pressure may be applied to press one or more composite structures and the base structure together, thereby forming an interference fit assembly.

In an embodiment, after the attaching, the composite structure may be patterned on the base structure. This may be accomplished by a lithography and etching procedure of all or a part of the individual layers and/or structures of the composite structure (the resulting mounting device may for instance have an appearance as the one shown in FIG. 5).

The aspects defined above and further aspects of embodiments of the invention are apparent from the examples of embodiment to be described hereinafter and are explained with reference to these examples of embodiment.

### BRIEF DESCRIPTION OF THE DRAWINGS

Embodiments of the invention will be described in more detail hereinafter with reference to examples of embodiment but to which the invention is not limited.

FIG. 1 illustrates a cross sectional view of a composite structure for a mounting device according to an exemplary embodiment of the invention.

FIG. 2 illustrates a cross sectional view of composite structures for a mounting device according to exemplary embodiments of the invention.

FIG. 3 illustrates a cross sectional view of two composite structures and a base structure pressed together for forming a mounting device according to an exemplary embodiment of the invention.

FIG. 4 illustrates a phase diagram indicating contributions of sp² hybridized carbon, sp³ hybridized carbon and hydrogen of a carbon comprising thermally conductive and electrically insulating structure of a mounting device according to an exemplary embodiment of the invention, wherein mechanical and thermal properties of the mounting device may be adjusted by configuring a manufacturing procedure in accordance with a desired section of the phase diagram.

FIG. 5 illustrates a cross sectional view of a mounting device according to another exemplary embodiment of the invention.

The illustrations in the drawings are schematical. In different drawings, similar or identical elements are provided with the same reference signs.

### DETAILED DESCRIPTION OF EXEMPLARY EMBODIMENTS

Before exemplary embodiments will be described in further detail referring to the figures, some general considerations of the present inventors will be presented based on which exemplary embodiments have been developed.

As miniaturization of substrates or mounting devices is going further on, meaning higher density of interconnection, multilayer build ups, active and passive component embedding, the energy consumption is increasing and hot spots are occurring. Heat affects tremendously the life time of components. This is a reason why the lifetime can be doubled by decreasing the working temperature of components by 10° C. With the implementation of heat dissipating layers, hot spots can be avoided by spreading the heat over the full substrate area. Therefore the lifetime of components in (i.e. embedded within) and/or on the substrate can be extended. In contrast to current materials these heat dissipating layers exhibit good thermal conductivities by maintaining low Dk (relative dielectric constant) values.

Conventionally, heat caused problems are solved by using thick heat sinks or metal compounds to minimize hot spots. Furthermore normally heat spreading materials exhibit good thermal conductivity because they are electrically conductive. Therefore designs have to be adopted to avoid short circuits. Regarding dielectric materials they possess thermal conductivities around or below 5 W/m K which are very low compared to metal or metal compounds. These materials are blocking the heat to flow away from hot spots which leads to a reduced component lifetime. Generally there is a fundamental contradiction between high thermal conductivity and low loss: Increase of thermal conductivity always leads to a rise of the Dk value. These problems can be solved according to exemplary embodiments, as described below.

RCC (Resin Coated Copper) foils are a common base material for PCBs (printed circuit boards). In contrast to prepreg foils, RCC foils possess no glass cloth inside. To increase the thermal performance of such an RCC foil, it is coated with a thermally conductive material according to exemplary embodiments. Appropriate coating methods are PECVD or sputter processes (PVD, ARC, etc.) which deliver layers directly on the adhesion promoting material surface.

Due to the fact that DLC (diamond like carbon)—as a preferred material for the thermally conductive and electrically insulating layer—and copper—as a preferred material for the electrically conductive carrier—are not directly compatible and lead to delaminations, a resin foil—as intermediate layer—can be pressed on the DLC surface to avoid a direct contact to thereby improve adhesion according to an exemplary embodiment of the invention. This thermally conductive composite structure or build up can be used instead of commonly used RCC foils to improve thermal performance of a resulting mounting device.

In a preferred embodiment, heat spreading can be realized by forming one or more vias into the foil to connect heat sources with spreading layers. The vias can be filled or coated with a metal or metal based composites. A thermal path should be made available for this purpose.

Concerning the deposited thermally conductive and electrically insulating layer, various thicknesses can be adjusted to obtain desired thermal conductivities. Furthermore, the thermally conductive and electrically insulating layer can be a dielectric aluminum compound or any thermally conductive but electrically non-conductive material. Heat spreading in x- and y-axis can be tremendously increased (wherein the xy-plane is perpendicular to a z-direction defining the thickness of the composite structure or the mounting device). Coating of RCC foils with amorphous carbon materials, aluminum compounds or other thermally conductive but electrically non-conductive materials can therefore be implemented to enhance the thermal conductivity of dielectric materials in x- and y-axis.

Applications of exemplary embodiments are any mounting devices for mounting electronic components where heat is generated and may cause problems.

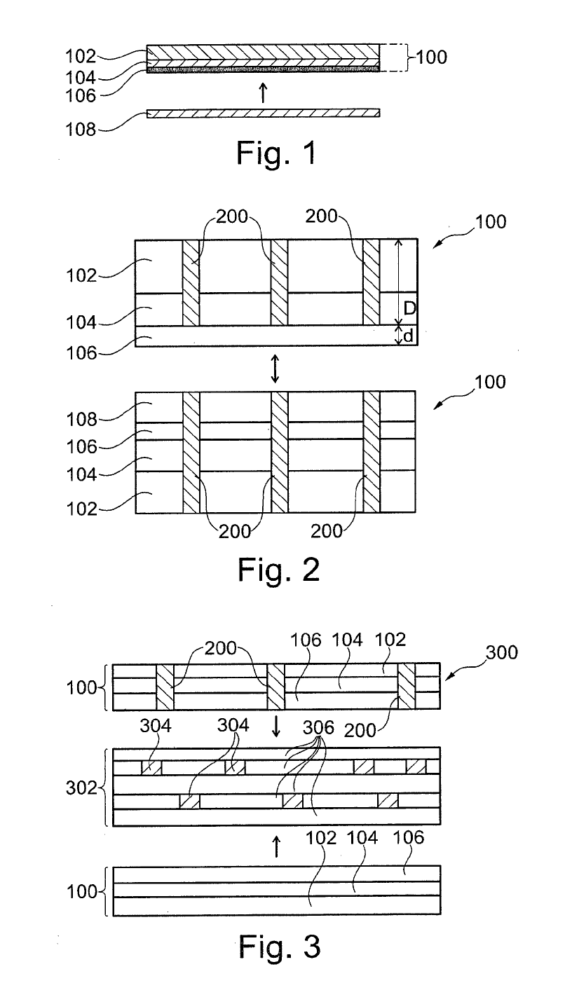

FIG. 1 illustrates a cross sectional view of a composite structure 100 for a mounting device 300 according to an exemplary embodiment of the invention.

The planar composite structure 100 comprises a layer-shaped electrically conductive carrier 102 which is embodied as a copper foil. An intermediate layer 104 consisting of pure epoxy resin is arranged directly on the electrically conductive carrier 102. The electrically conductive carrier 102 and the intermediate layer 104 are together embodied as a Resin Coated Copper (RCC) foil. A thermally conductive and electrically insulating layer 106, which is embodied as a diamond like carbon (DLC) layer, has been deposited directly on the intermediate layer 104, for instance by PVD.

The composite structure 100 furthermore comprises an optional cover layer 108, here made of pure epoxy-based resin as well, which can be attached onto the composite structure 100 for covering the surface of the thermally conductive and electrically insulating layer 106.

The composite structure 100 shown in FIG. 1 can be used as a substitute for any conventional metal layer used for mounting devices, for instance as a substitute for conventional copper foils. In contrast to such conventional copper foils, the composite structure 100 has the advantage of a significantly improved thermal conductivity in view of the high thermal conductivity of the thermally conductive and electrically insulating layer 106 of DLC. At the same time, the composite structure 100 is only minimal thicker than a conventional copper foil and can therefore be used for manufacturing compact mounting devices. Since the direct adhesion between copper and DLC is poor, the resin material of the intermediate layer 104 functions as an adhesion promoting layer, thereby resulting in a mechanically robust composite structure 100. Alternative adhesion promoting layers are possible, for instance in the form of a coating of silane.

FIG. 2 illustrates a cross sectional view of two composite structures 100 for a mounting device 300 according to other exemplary embodiments of the invention.

One of these composite structures 100 comprises a cover layer 108 as described referring to FIG. 1, whereas the other one of the composite structures 100 is free of such a cover layer 108 (i.e. is configured as a three composite structure).

As can be taken from FIG. 2, the combined thickness, D, of the electrically conductive carrier 102 and the intermediate layer 104, here embodied as RCC foil, can be in a range between 9 μm and 18 μm. A thickness, d, of the thermally conductive and electrically insulating layer 106 can be in a range between 1 μm and 3 μm. The thickness of the optional cover layer 108 can be selected appropriately for a certain application, for instance in a range between 1 μm and 10 μm.

The composite structures 100 shown in FIG. 2 further comprise a plurality of vias 200 (which may for instance be arranged in a matrix like pattern, i.e. in rows and columns) vertically extending through the composite structures 100 and being filled with copper as a thermally conductive material to thereby thermally couple the thermally conductive and electrically insulating layer 106 to the electrically conductive carrier 102 through the intermediate layer 104. This accomplishes efficient heat spreading over the entire mounting device and prevents hotspots.

FIG. 3 illustrates a cross sectional view of two composite structures 100 of the type as shown in FIG. 1 and FIG. 2 and a base structure 302 (which may also be denoted as a core structure) of a mounting device 300 according to yet another exemplary embodiment of the invention.

The mounting device 300 is configured for mounting one or more electronic components (not shown, for instance packaged semiconductor chips) thereon. The mounting device 300 comprises the base structure 302 which, in turn, comprises an electrically conductive structure 304 of copper and an electrically insulating structure 306 of prepreg or FR4. The electrically conductive structure 304 can be formed of copper structures, and can be constituted by one or more continuous and/or patterned layers of electrically conductive material. The electrically insulating structure 306 can be formed of prepreg or FR4 structures, and can be constituted by one or more continuous and/or patterned layers of electrically insulating material.

Furthermore, the mounting device 300 comprises two composite structures 100 as described above, each of which being attached at its respective thermally conductive and electrically insulating layer 106 to a respective main surface of the base structure 302. Thus, the base structure 302 and the composite structures 100 may be connected to one another by pressing, thereby forming an interference fit assembly constituting the mounting device 300.

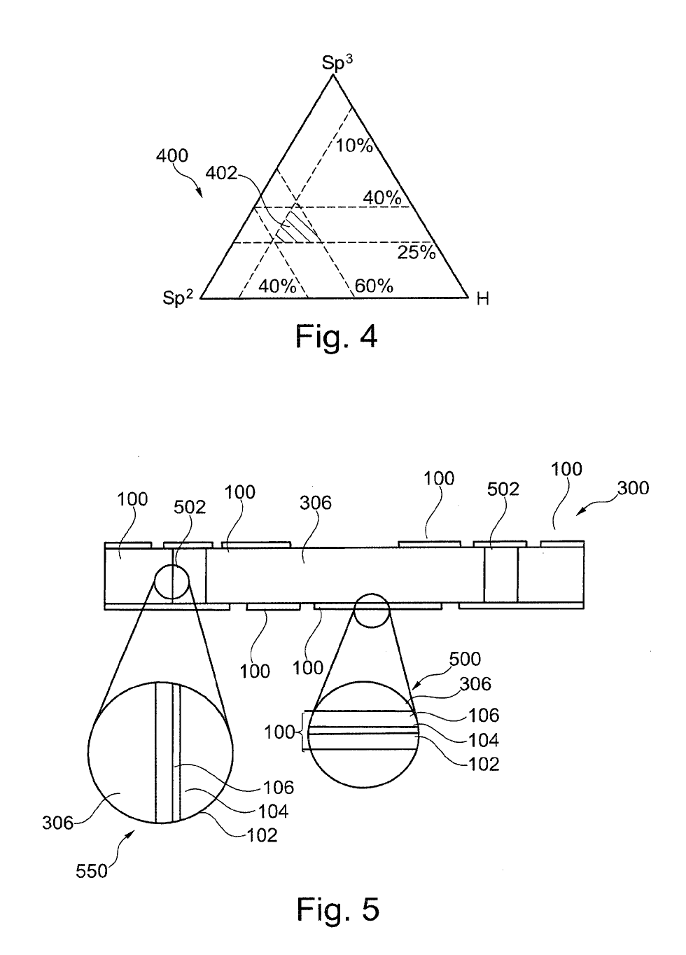

FIG. 4 illustrates a phase diagram 400 indicating contributions of sp² hybridized carbon, sp³ hybridized carbon and hydrogen of a carbon comprising thermally conductive and electrically insulating structure 106 of a mounting device 300 according to an exemplary embodiment of the invention, wherein mechanical and thermal properties of the mounting device 300 may be adjusted by configuring a manufacturing procedure in accordance with a desired section of the phase diagram 400.

According to the phase diagram 400, the thermally conductive and electrically insulating structure 106 of diamond like carbon (DLC) is a hydrogen (H) comprising amorphous carbon coating with a mixture of sp² and sp³ hybridized carbon. Preferably, the portion of sp² hybridized carbon is in a range between 40 and 60 weight percent of the thermally conductive and electrically insulating structure 106, the portion of sp³ hybridized carbon is in a range between 25 and 40 weight percent of the thermally conductive and electrically insulating structure 106, and the percentage of hydrogen is above 10 weight percent preferably not above 40 weight percent. When the thermally conductive and electrically insulating structure 106 is formed by sputtering/physical vapor deposition PVD, the percentage of sp² hybridized carbon is high. When however plasma enhanced chemical vapor deposition PECVD is used for forming the thermally conductive and electrically insulating structure 106, a higher hydrogen percentage is obtained. With a high percentage of sp² hybridized and sp³ hybridized carbon, a high thermal conductivity of the thermally conductive and electrically insulating structure 106 may be obtained. With a high hydrogen percentage, a mechanically stable thermally conductive and electrically insulating structure 106 is obtained. By a selection of the manufacturing procedure for instance also adjustment of the precise process parameters and/or, if desired, a combination of the above-mentioned manufacturing procedures, the mechanical and thermal properties of the thermally conductive and electrically insulating structure 106 may be precisely set. A particularly appropriate composition in terms of the mechanical and thermal properties is shown in FIG. 4 with an area denoted with reference numeral 402.

FIG. 5 illustrates a cross sectional view of a mounting device 300 according to another exemplary embodiment of the invention, embodied as a printed circuit board.

The mounting device 300 is embodied as a printed circuit board and comprises electrically insulating structure 306, for instance made of FR4 material. On two opposing main surfaces of the electrically insulating structure 304, patterned composite structures 100 (compare FIG. 1) are arranged, wherein exposed surface portions of the composite structures 100 serve for electrically mounting electronic components (not shown), and another portion of the composite structures 100 is in direct contact with the FR4 material of the electrically insulating structure 306 and promotes the heat dissipation properties of the mounting device 300. The exposed surfaces of the composite structures 100 are electrically conductive, whereas the surfaces of the composite structures 100 in an interior of the mounting device 300 in direct contact with the electrically insulating structure 306 are electrically insulating and thermally conductive, see detail 500.

FIG. 5 furthermore shows through holes through the electrically insulating structure 306 filled with vias 502, compare also detail 550. The vias 502 may comprise a post-shaped central portion embodied as electrically conductive carrier 102 (for instance made of copper) covered with a hollow cylindrical adhesion promoting structure in form of the tubular intermediate layer 104 (for instance a resin layer) which, in turn, is covered with a hollow cylindrical or tubular thermally conductive and electrically insulating layer 106 (for instance made of DLC).

FIG. 5 shows that each conventionally used copper foil of a PCB can be substituted by a sandwich composition of the type shown as composite structure 100 in FIG. 1. However, not only foils can be substituted by such a composition, but also cylindrical bodies such as vias 502, or other electrically conductive structures. The dimension of any of such structures is only increased in thickness by a minimum extent, for instance by 2 μm to 3 μm (i.e. a summed dimension of intermediate layer 104 and thermally conductive and electrically insulating layer 106).

It should be noted that the term “comprising” does not exclude other elements or steps and the “a” or “an” does not exclude a plurality. Also elements described in association with different embodiments may be combined.

It should also be noted that reference signs in the claims shall not be construed as limiting the scope of the claims.

Implementation of the invention is not limited to the preferred embodiments shown in the figures and described above. Instead, a multiplicity of variants are possible which use the solutions shown and the principle according to the invention even in the case of fundamentally different embodiments.

1. A composite structure for use as a constituent of a mounting device, wherein the composite structure comprises:
an electrically conductive carrier;
an intermediate layer comprising adhesion promoting material and being arranged on the electrically conductive carrier; and
a thermally conductive and electrically insulating layer on the intermediate layer.

2. The composite structure according to claim 1, wherein the electrically conductive carrier comprises or consists of copper.

3. The composite structure according to claim 1, wherein the intermediate layer comprises resin.

4. The composite structure according to, wherein the thermally conductive and electrically insulating layer comprises at least one of the group consisting of diamond-like carbon, a nitride, an oxide, and a thermally conductive polymer.

5. The composite structure according to claim 1, wherein the thermally conductive and electrically insulating layer is made of a material having a value of the thermal conductivity of at least 2 W/m K.

6. The composite structure according to claim 1, wherein a thickness of the thermally conductive and electrically insulating layer is in a range between 150 nm and 50 μm.

7. The composite structure according to claim 1, wherein the electrically conductive carrier and the intermediate layer together have a thickness in a range between 4 μm and 100 μm.

8. The composite structure according to claim 1, further comprising:
a cover layer covering the thermally conductive and electrically insulating layer.

9. The composite structure according to claim 1, further comprising:
at least one via extending through at least part of the composite structure and being filled with a thermally conductive material to thereby thermally couple the thermally conductive and electrically insulating layer to the electrically conductive carrier by the at least one via through the intermediate layer.

10. The composite structure according to claim 1, configured as a layer sequence.

11. A mounting device for mounting electronic components, wherein the mounting device comprises:
a base structure comprising an electrically conductive structure and an electrically insulating structure;
at least one composite structure according to claim 1 which is attached at its thermally conductive and electrically insulating layer to at least one main surface of the base structure.

12. The mounting device according to claim 11, wherein the electrically conductive structure comprises or consists of copper.

13. The mounting device according to claim 11, wherein the electrically insulating structure comprises or consists of at least one of the group consisting of prepreg, resin, FR4, and resin soaked glass fibres.

14. The mounting device according to claim 11, wherein an exposed surface of the thermally conductive and electrically insulating layer is, partially or entirely, directly connected to the electrically insulating structure.

15. The mounting device according to claim 11, comprising
a further composite structure, wherein the base structure is sandwiched between the composite structure and the further composite structure.

16. The mounting device according to claim 11, configured as one of the group consisting of a circuit board, a printed circuit board, an interposer, and a substrate.

17. A method of manufacturing a composite structure for use as a constituent of a mounting device, wherein the method comprises:
providing an intermediate layer, which comprises adhesion promoting material, on an electrically conductive carrier;
forming a thermally conductive and electrically insulating layer on the intermediate layer.

18. The method according to claim 17, wherein the electrically conductive carrier and the intermediate layer are configured as a Resin Coated Copper foil.

19. The method according to claim 17, wherein the thermally conductive and electrically insulating layer is formed on the intermediate layer by one of group consisting of physical vapour deposition, chemical vapour deposition, and plasma enhanced chemical vapour deposition.

20.-22. (canceled)
